(19) United States
(12) Patent Application Publication
(10) Pub. No.: US 2025/0142957 A1
(43) Pub. Date: May 1, 2025

(54) N-CHANNEL COUPLED WITH P-CHANNEL AND METHODS OF MANUFACTURE

(71) Applicant: Applied Materials, Inc., Santa Clara, CA (US)

(72) Inventors: Sai Hooi Yeong, Cupertino, CA (US); Steven C.H. Hung, Sunnyvale, CA (US); Veeraraghavan S. Basker, Fremont, CA (US); Benjamin Colombeau, San Jose, CA (US); Balasubramanian Pranatharthiharan, San Jose, CA (US)

(73) Assignee: Applied Materials, Inc., Santa Clara, CA (US)

(21) Appl. No.: 18/911,689

(22) Filed: Oct. 10, 2024

Related U.S. Application Data
(60) Provisional application No. 63/545,823, filed on Oct. 26, 2023.

(51) Int. Cl. H01L 27/118

(52) U.S. Cl. CPC H10D 84/907; H10D 84/953

(57) ABSTRACT

Logic devices and methods of manufacturing logic devices are provided. The semiconductor logic device includes an n-channel gate-all-around (n-GAA) field-effect transistor on a substrate integrated with a p-channel gate-all-around (p-GAA) field-effect transistor on the substrate adjacent to the n-channel gate-all-around (p-GAA) field-effect transistor. The n-channel gate-all-around (n-GAA) field effect-transistor has a structure including a plurality of layers comprising silicon and a corresponding plurality of layers comprising at least 25% germanium alternatingly arranged in stacked pairs extending between a source region and a drain region, and the p-channel gate-all-around (p-GAA) field-effect transistor has a plurality of layers comprising in a range of from 5% to 15% germanium and a corresponding plurality of layers comprising at least 25% germanium alternatingly arranged in stacked pairs.

### CROSS-REFERENCE TO RELATED APPLICATIONS

This application claims priority to U.S. Provisional Application No. 63/545,823, filed Oct. 26, 2023, the entire disclosure of which is hereby incorporated by reference herein.

### TECHNICAL FIELD

Embodiments of the present disclosure pertain to the field of electronic devices and methods and apparatus for manufacturing electronic devices. More particularly, embodiments of the disclosure provide methods for forming logic devices and transistors, e.g., gate-all-around devices (GAA), field-effect transistors (FinFETs), and complementary field effect transistors (CFETs), having an n-channel coupled with a p-channel.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (finFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. FinFETs, however, have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a gate-all-around (GAA) structure.

The GAA device structure includes several lattice matched channels suspended in a stacked configuration and connected by source/drain regions. The GAA structure provides good electrostatic control and can find broad adoption in complementary metal oxide semiconductor (CMOS) wafer manufacturing. Post-high-k (HK) nitridation is one attractive feature for CMOS equivalent oxide thickness (EOT) scaling, which allows high performance transistors. The post-HK nitridation, however, degrades p-channel metal-oxide semiconductor (PMOS) transistor end-of-line (EOL) negative bias temperature instability (NBTI), resulting in a trade-off to the EOT scaling gain.

Accordingly, there is a need in the art for logic devices that allow MOS EOT scaling with RO performance boosting without degrading performance reliability. Additionally, there is a need in the art for methods and apparatus for forming the logic devices.

### SUMMARY

One or more embodiments of the disclosure are directed to a method of forming a semiconductor logic device. In one or more embodiments, a method of forming a semiconductor logic device comprises: forming a first superlattice structure on a substrate, the first superlattice structure comprising a plurality of first layers comprising silicon and a corresponding plurality of second layers comprising at least 25% germanium alternatingly arranged in a plurality of stacked pairs extending between a source region and a drain region; forming a second superlattice structure on the substrate, the second superlattice structure comprising a plurality of third layers comprising in a range of from 5% to 15% germanium and a corresponding plurality of fourth layers comprising at least 25% germanium alternatingly arranged in a plurality of stacked pairs extending between the source region and the drain region; and selectively etching the plurality of second layers and the plurality of fourth layers simultaneously to form an nMOS transistor and a pMOS transistor.

Further embodiments of the disclosure are directed to semiconductor logic devices. In one embodiment, a semiconductor logic device comprises: an n-channel gate-all-around (n-GAA) field-effect transistor on a substrate; and a p-channel gate-all-around (p-GAA) field-effect transistor on the substrate adjacent to the n-channel gate-all-around (n-GAA) field-effect transistor, wherein the n-channel gate-all-around (n-GAA) field-effect transistor comprises a first superlattice structure including a plurality of first layers comprising silicon and a corresponding plurality of second layers comprising at least 25% germanium alternatingly arranged in a plurality of stacked pairs extending between a source region and a drain region, and wherein the p-channel gate-all-around (p-GAA) field-effect transistor includes a plurality of third layers comprising in a range of from 5% to 15% germanium and a corresponding plurality of fourth layers comprising at least 25% germanium alternatingly arranged in a plurality of stacked pairs extending between the source region and the drain region.

Still further embodiments of the disclosure are directed to non-transitory computer readable medium including instructions, that, when executed by a controller of a processing chamber, causes the processing chamber to perform the operations of: form a first superlattice structure on a substrate, the first superlattice structure comprising a plurality of first layers comprising silicon and a corresponding plurality of second layers comprising at least 25% germanium alternatingly arranged in a plurality of stacked pairs extending between a source region and a drain region; form a second superlattice structure on the substrate, the second superlattice structure comprising a plurality of third layers comprising in a range of from 5% to 15% germanium and a corresponding plurality of fourth layers comprising at least 25% germanium alternatingly arranged in a plurality of stacked pairs extending between the source region and the drain region; and selectively etch the plurality of second layers and the plurality of fourth layers simultaneously to form an nMOS transistor and a pMOS transistor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments described herein are illustrated by way of example and not limited in the figures of the accompanying drawings in which like references indicate similar elements.

FIG. 1 depicts a process flow diagram of a method according to one or more embodiments described herein;

FIG. 2 illustrates a cross-sectional view of a device according to one or more embodiments;

FIG. 2A illustrates a cross-sectional view of a device according to one or more embodiments;

FIG. 2B illustrates a cross-sectional view of a device according to one or more embodiments;

FIG. 2C illustrates a cross-sectional view of a device according to one or more embodiments;

FIG. 3A illustrates a cross-sectional view of a device according to one or more embodiments;

FIG. 3B illustrates a cross-sectional view of a device according to one or more embodiments;

FIG. 3C illustrates a cross-sectional view of a device according to one or more embodiments;

FIG. 4 illustrates a cross-sectional view of a device according to one or more embodiments;

FIG. 5 illustrates a cross-sectional view of a device according to one or more embodiments;

FIG. 6A illustrates a cross-sectional view of a device according to one or more embodiments;

FIG. 6B illustrates a cross-sectional view of a device according to one or more embodiments; and

FIG. 7 is a schematic top-view diagram of an example multi-chamber processing system according to one or more embodiments;

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

Spatially relative terms, such as “beneath,” “below,” “lower,” “above,” “upper” and the like, may be used herein for ease of description to describe one element's relationship to other element(s) or as illustrated in the Figures. It will be understood that the spatially relative terms are intended to encompass different orientations of a device, such as a semiconductor device, in use or operation in addition to the orientation depicted in the Figures. For example, if the device in the Figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

As used in this specification and the appended claims, the term “substrate” or “wafer” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

The substrate surface may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, vias which have one or more sidewall extending into the substrate to a bottom, and slot vias. The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, or 40:1.

The term “on” indicates that there is direct contact between elements. The term “directly on” indicates that there is direct contact between elements with no intervening elements.

As used in this specification and the appended claims, the terms “precursor,” “reactant,” “reactive gas” and the like are used interchangeably to refer to any gaseous species that can react with the substrate surface.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD processing chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the semiconductor substrate. In the sputtering processes, the sputtering target is bombarded by energetic ions, such as a plasma, causing material to be knocked off the target and deposited as a film on the semiconductor substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

Plasma sputtering may be accomplished using either DC sputtering or RF sputtering. Plasma sputtering typically includes a magnetron positioned at the back of a sputtering target including two magnets of opposing poles magnetically coupled at their back through a magnetic yoke to project a magnetic field into the processing space to increase the density of the plasma and enhance the sputtering rate from a front face of the target. Magnets used in the magnetron are typically closed loop for DC sputtering and open loop for RF sputtering.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., hydrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, entering the channel at the source(S) is designated Is and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double-or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nano-slabs, or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor. The stacked horizontal gate-all-around (hGAA) transistor may comprise any suitable number of stacked horizontal gate-all-around (hGAA) channels. In some embodiments, the stacked horizontal gate-all-around (hGAA) transistor contains in a range of from 2 to 10 stacked horizontal gate-all-around (hGAA) channels.

One example of gate-all-around (GAA) technology is complementary field effect transistor (CFET). As used herein, the term “complementary field-effect transistor (CFET)” refers to a transistor that includes NMOS FET devices and PMOS FET devices stacked on each other. Each of the NMOS FET devices and the PMOS FET devices that form the CFET are GAA transistors or hGAA transistors. CFET transistors have increased on-chip device density and reduced area consumption when compared to GAA transistors.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

The embodiments of the disclosure are described by way of the Figures, which illustrate devices (e.g., such as gate-all-around devices, FinFETs, and CFETs) and processes for forming transistors in accordance with one or more embodiments of the disclosure. The processes shown are merely illustrative possible uses for the disclosed processes, and the skilled artisan will recognize that the disclosed processes are not limited to the illustrated applications.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great detail to avoid unnecessarily obscuring this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

One or more embodiments of the disclosure are described with reference to the Figures. In one or more embodiments, an n-channel field-effect transistor is coupled or integrated with a p-channel field-effect transistor to form a semiconductor logic device. In one or more embodiments, an n-channel gate-all-around field-effect transistor is coupled or integrated with a p-channel gate-all-around field-effect transistor to form a semiconductor logic device. In specific embodiments, a silicon germanium (SiGe) channel is used to boost the EOT scaling performance of a PMOS device in combination with a silicon (Si) channel NMOS device to form a gate-all-around nanosheet CMOS device. In other specific embodiments, a silicon germanium (SiGe) channel is used to boost the EOT scaling performance of a PMOS device in combination with a silicon (Si) channel NMOS device to form a CMOS device. In one or more embodiments, the combination of an n-channel gate-all-around field-effect transistor with a p-channel gate-all-around field-effect transistor results in an EOT scaling improvement in a range of from greater than 5 Å to 1.5 Å, and an overall CMOS RO speed gain of greater than 5% without causing a decrease in reliability performance. In one or more embodiments, the SiGe channel PMOS may also contribute to other benefits including, but not limited to, a reduction in threshold voltage (Vt) and higher hole mobility. In other embodiments, the semiconductor logic device that is formed is compatible with FinFET and CFET (monolithic/sequential via hybrid bonding) technology in addition to compatibility with GAA nanosheet technology.

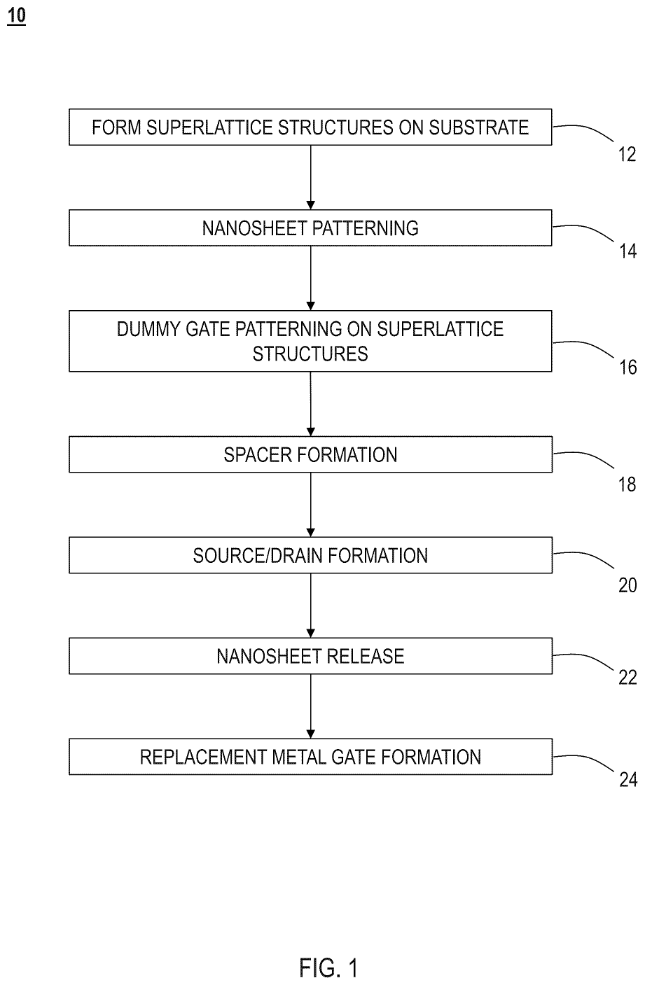

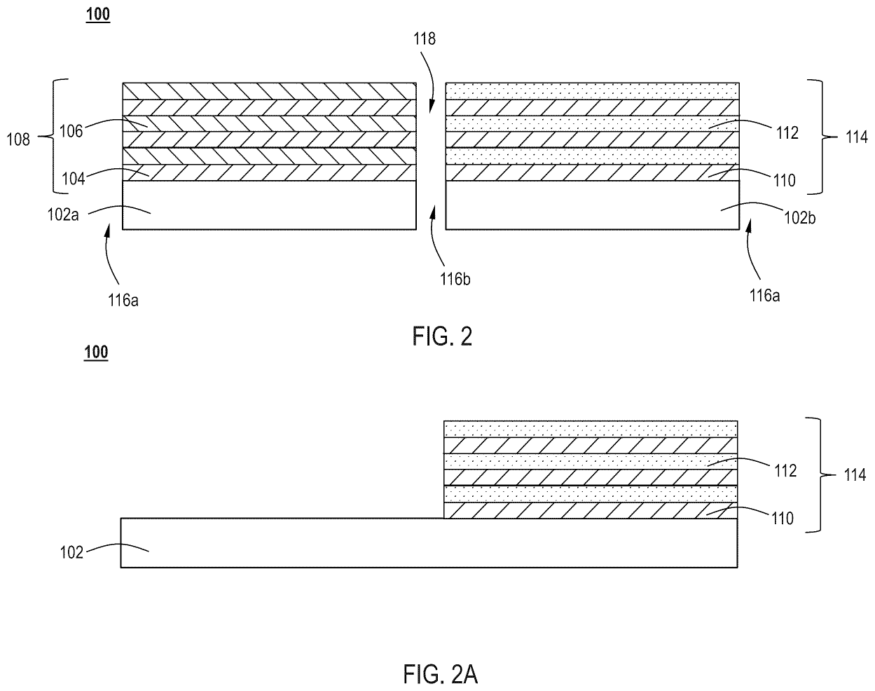

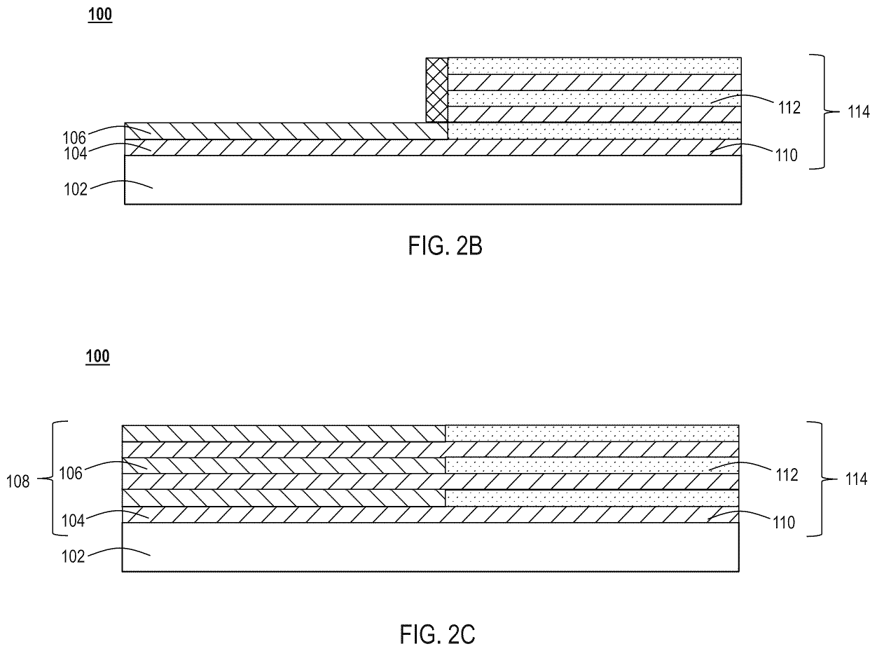

FIG. 1 illustrates a process flow diagram for a method 10 for forming a semiconductor logic device, such as gate-all-around devices, FinFETs, and CFETs, in accordance with some embodiments of the present disclosure. FIGS. 2A-7 depict the stages of fabrication of semiconductor logic structures in accordance with some embodiments of the present disclosure. In one or more embodiments, a silicon germanium (SiGe) channel is integrated with optimization of nitridation of the interlayer dielectric and high-k dielectric stack for PMOS.

The method 10 is described below with respect to FIGS. 1-7. FIGS. 1-7 are cross-sectional views of an electronic device (e.g., a GAA, FinFET, CFET) according to one or more embodiments. The method 10 may be part of a multi-step fabrication process of a semiconductor device. Accordingly, the method 10 may be performed in any suitable process chamber coupled to a cluster tool. The cluster tool may include process chambers for fabricating a semiconductor device, such as chambers configured for etching, deposition, physical vapor deposition (PVD), chemical vapor deposition (CVD), oxidation, or any other suitable chamber used for the fabrication of a semiconductor device.

FIGS. 2-7 are the fabrication steps of operations 12 through 24 in FIG. 1. Referring to FIG. 1, the method 10 of forming the device 100 begins at operation 12, by providing a substrate 102 and forming superlattice structures on the substrate 102. In some embodiments, the substrate 102 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100>or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the semiconductor substrate 102 comprises a semiconductor material, e.g., silicon (Si), carbon (C), germanium (Ge), silicon germanium (SiGe), germanium tin (GeSn), other semiconductor materials, or any combination thereof. In one or more embodiments, the substrate 102 comprises one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof.

With reference to FIG. 2, in one or more embodiments, a first superlattice structure 114 is formed on a top surface of the substrate 102 and a second superlattice structure 108 is formed on a top surface of the substrate 102 adjacent to the first superlattice structure 114. In one or more embodiments, the first superlattice structure 114 form the NMOS region of the semiconductor memory device 100 and the second superlattice structure 108 forms the PMOS region of the semiconductor memory device 100.

In one or more embodiments, the first superlattice structure 114 comprises a plurality of first layers 112 comprising silicon and a corresponding plurality of second layers 110 comprising at least 25% germanium alternatingly arranged in a plurality of stacked pairs extending between a source region 116a and a drain region 116b. In one or more embodiments, the plurality of second layers 110 comprise silicon germanium (SiGe) having at least 25% germanium (Ge). In some embodiments, the amount of germanium (Ge) in the plurality of second layers is in a range of from >25% to 100%, including in a range of from >25% to 90%, or in a range of from >25% to 75%, or in a range of from >25% to 50% germanium.

In one or more embodiments, the second superlattice structure 108 comprises a plurality of third layers 106 comprising in a range of from 5% to 15% germanium and a corresponding plurality of fourth layers 104 comprising at least 25% germanium alternatingly arranged in a plurality of stacked pairs extending between the source region 116a and the drain region 116b. In one or more embodiments, the plurality of fourth layers 104 comprise silicon germanium (SiGe) having at least 25% germanium (Ge). In some embodiments, the amount of germanium (Ge) in the plurality of fourth layers 104 is in a range of from >25% to 100%, including in a range of from >25% to 90%, or in a range of from >25% to 75%, or in a range of from >25% to 50% germanium. In one or more embodiments, the plurality of third layers 106 comprise silicon germanium (SiGe) having in a range of from 5% to 15% germanium, including in a range of from 5% to 10% germanium.

In one or more embodiments, the first superlattice structure 114 may be formed by any suitable means known to the skilled artisan. In some embodiments, the first superlattice structure 114 is formed by epitaxial growth of the plurality of first layers 112 and the corresponding plurality of second layers 110.

In one or more embodiments, the second superlattice structure 108 may be formed by any suitable means known to the skilled artisan. In some embodiments, the second superlattice structure is formed by bottom-p growth of the plurality of fourth layer 104 followed by bottom-up growth or HCl sidewall etch back of the plurality of third layers 106, as illustrated in FIGS. 2A through 2C, where HCl is the etching chemistry performed with the EPI chamber in situ.

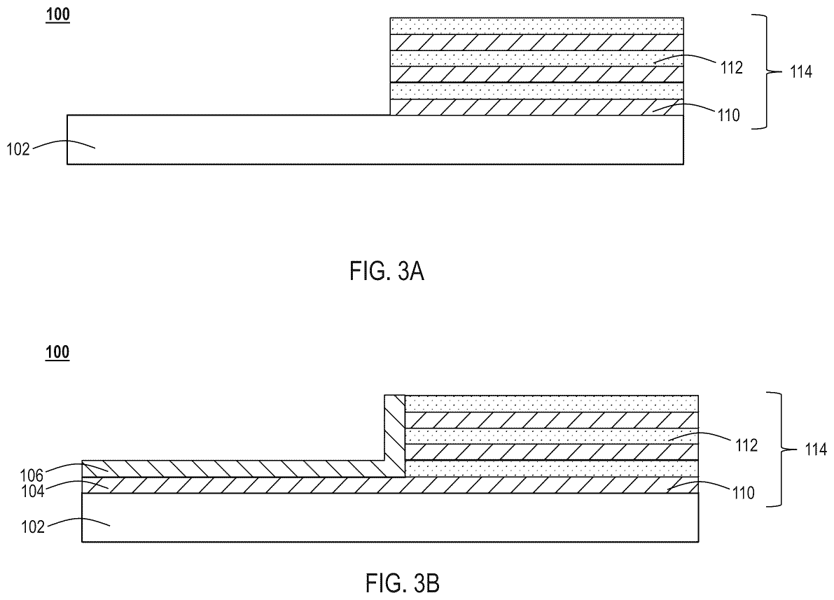

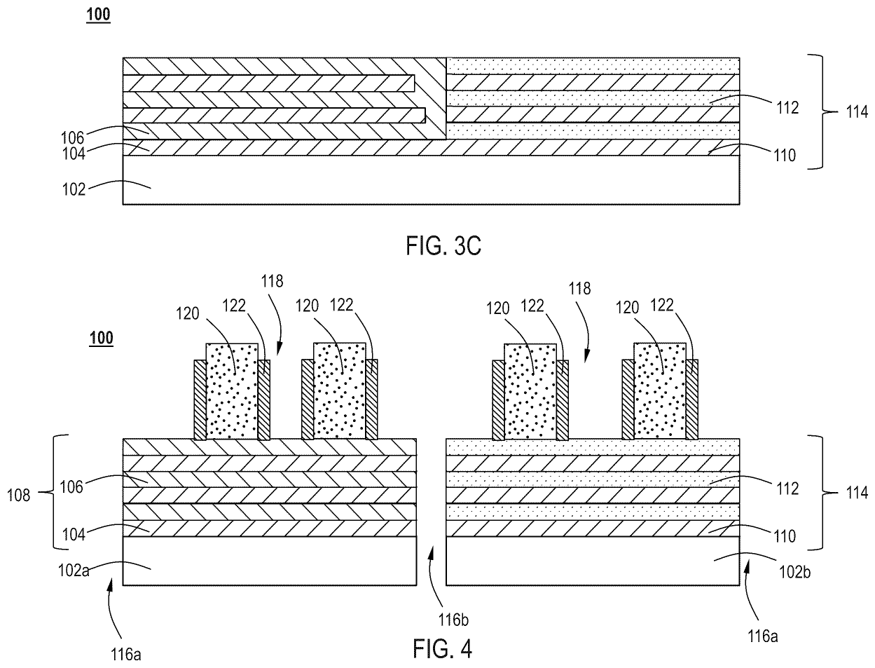

In other embodiments, the second superlattice structure 108 may be formed by bottom-p growth of the plurality of fourth layer 104 followed by conformal deposition of the plurality of third layers 106, as illustrated in FIGS. 3A through 3C.

Referring to FIGS. 2-7, in one or more embodiments, the plurality of fourth layers 104 and corresponding plurality of third layers 106 can comprise any number of lattice matched pairs suitable for forming the superlattice structure 108. In one or more embodiments, the plurality of second layers 110 and corresponding plurality of first layers 112 can comprise any number of lattice matched pairs suitable for forming the superlattice structure 114. In some embodiments, the plurality of third layers 106 and corresponding plurality of fourth layers 104 comprise from about 4 to about 20 pairs of lattice matched materials. In some embodiments, the plurality of first layers 112 and corresponding plurality of second layers 110 comprise from about 4 to about 20 pairs of lattice matched materials.

In one or more embodiments, the thickness, t₁, of the plurality of first layers 112, the plurality of second layers 110, the plurality of third layers 106, and the plurality of fourth layers 104 are independently in the range of from about 2 nm to about 30 nm, in the range of from about 3 nm to about 20 nm, or in a range of from about 2 nm to about 10 nm.

Referring to FIG. 1 and FIG. 4, at operation 16, in one or more embodiments, a dummy gate structure 120 is formed atop the first superlattice structure 114 and the second superlattice structure 108. The dummy gate structure 120 defines the channel region of the transistor device. The dummy gate structure 120 defines the channel region 118 of the transistor device. The dummy gate structure 120 may be formed using any suitable conventional deposition and patterning process known in the art. In one or more embodiments, the dummy gate structure 120 comprises one or more of tungsten (W), cobalt (Co), molybdenum (Mo), ruthenium (Ru), titanium nitride (TiN), tantalum nitride (TaN), titanium aluminum (TiAl), and N doped polysilicon. In one or more embodiments, the channel region 118 separates the dummy gate structure 120 from an adjacent dummy gate structure.

Referring to FIG. 1 and FIGS. 4 through 6, in some embodiments, at operation 18, sidewall spacers 122 are formed along outer sidewalls of the dummy gate structure 120 and on the superlattice 108,114. The sidewall spacers 122 may comprise any suitable insulating materials known in the art, for example, silicon nitride, silicon oxide, silicon oxynitride, silicon carbide, or the like. In some embodiments, the sidewall spacers are formed using any suitable conventional deposition and patterning process known in the art, such as atomic layer deposition, plasma enhanced atomic layer deposition, plasma enhanced chemical vapor deposition, low-pressure chemical vapor deposition, or isotropic deposition.

At operation 20, the channel region 118 is recessed to form a source trench 116a and a drain trench 116b. In one or more embodiments, a source trench 116a and a drain trench 116b are formed adjacent (i.e., on either side) the first superlattice structure 114 and the second superlattice structure 108. In one or more embodiments, the source trench or region 116a is adjacent to a first end of the first superlattice structure 114 and the drain trench or region 116b is adjacent to a second opposing end of the first superlattice structure 114.

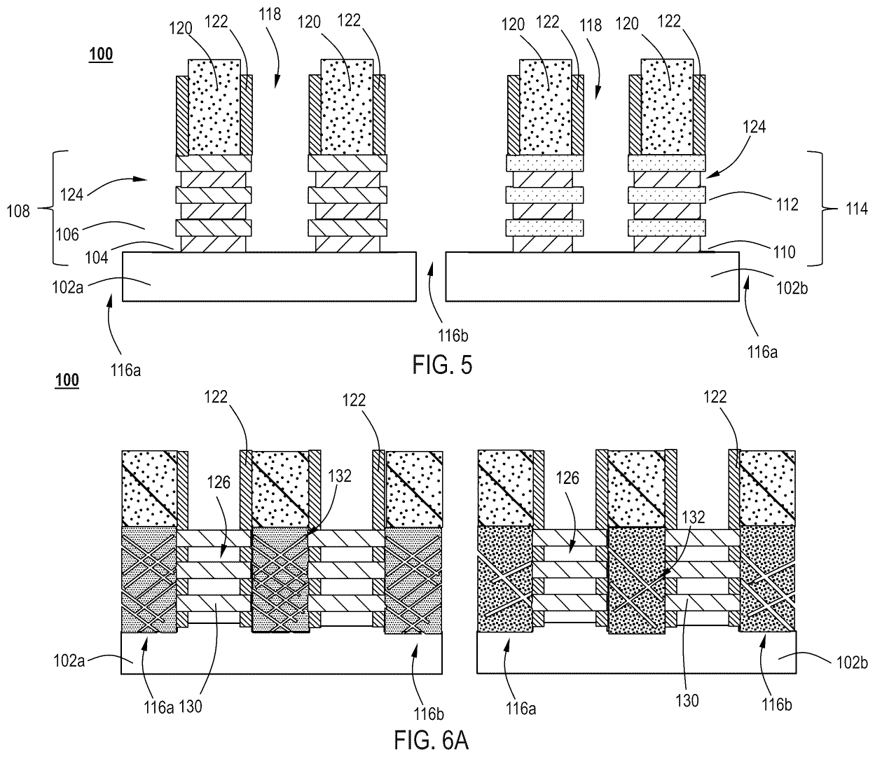

Referring to FIG. 1, at operation 22, the formation of the semiconductor device, e.g., GAA, continues according to traditional procedures with nanosheet release and replacement metal gate formation (operation 24). Specifically, as illustrated in FIG. 5, in one or more embodiments, the plurality of second layers 104 and the plurality of fourth layers 110 are selectively recessed from the sides of the superlattice structures 108, 114 to form a recess region 124.

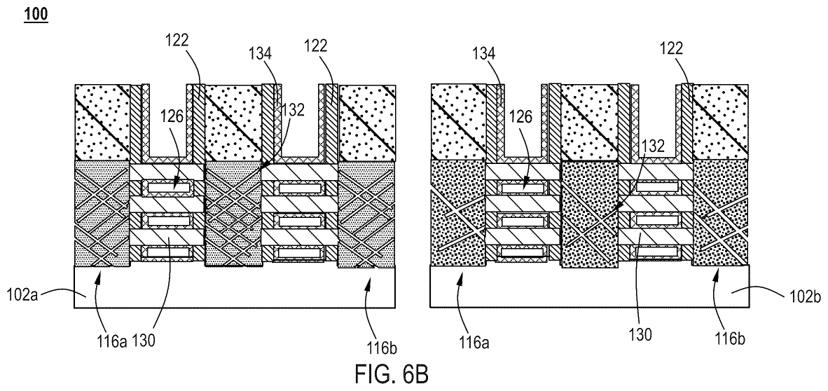

Referring to FIG. 6A, the silicon germanium (SiGe) layers containing greater than 25% germanium (i.e., the plurality of second layers 104 and plurality of fourth layers 110) are selectively etched to form channel nanowires. The silicon germanium (SiGe) layers containing greater than 25% germanium (i.e., the plurality of second layers 104 and plurality of fourth layers 110) may be removed using any well-known etchant that is selective to the plurality of first layers 106 and to the plurality of third layers 112 where the etchant etches the silicon germanium (SiGe) layers containing greater than 25% germanium (i.e., the plurality of second layers 104 and plurality of fourth layers 110) at a significantly higher rate than the plurality first layers 106 and the plurality of third layers 112. In some embodiments, a selective dry etch or wet etch process may be used. In some embodiments, the layers of silicon germanium containing greater than 25% germanium may be selectively removed using a wet etchant such as, but not limited to aqueous carboxylic acid/nitric acid/HF solution and aqueous citric acid/nitric acid/HF solution. The removal of the silicon germanium (SiGe) layers containing greater than 25% germanium (i.e., the plurality of second layers 104 and plurality of fourth layers 110) leaves voids 126 between the plurality of first layers 106 and plurality of third layers 113. The voids 126 between the plurality of first layers 106 and plurality of third layers 113 independently have a thickness of about 3 nm to about 20 nm. The remaining plurality of first layers 106 and plurality of third layers 113 form a vertical array of channel nanowires 130 that are coupled 132 to the source/drain regions 116a, 116b. The channel nanowires 130 run parallel to the top surface of the substrate 102 and are aligned with each other to form a single column of channel nanowires.

The etch process of operation 22 may include any suitable etch process that is selective to the spacer material 122. In some embodiments the etch process of operation 22 comprises one or more of a wet etch process or a dry etch process.

In some embodiments, the dry etch process may include any conventional plasma etch, or any suitable remote plasma-assisted dry etch process known to the skilled artisan. In one or more embodiments, an etch process includes the device being exposed to H₂, NF₃, and/or NH₃ plasma species, e.g., plasma-excited hydrogen and fluorine species. For example, in some embodiments, the device may undergo simultaneous exposure to H₂, NF₃, and NH₃ plasma. The etch process may be performed in any suitable preclean chamber, which may be integrated into one of a variety of multi-processing platforms known to the skilled artistan. The wet etch process may include a hydrofluoric (HF) acid last process, i.e., the so-called “HF last” process, in which HF etching of surface is performed that leaves surface hydrogen termination. Alternatively, any other liquid-based pre-epitaxial pre-clean process may be employed. In some embodiments, the process comprises a sublimation etch for native oxide removal. The etch process can be plasma or thermally based. The plasma processes can be any suitable plasma (e.g., conductively coupled plasma, inductively coupled plasma, microwave plasma).

Referring to FIG. 6B, in one or more unillustrated embodiments, a high-k dielectric material 134 is deposited. The high-k dielectric material 134 can be any suitable high-k dielectric material deposited by any suitable deposition technique known to the skilled artisan. The high-k dielectric material 134 of some embodiments comprises hafnium oxide. In some embodiments, a conductive material (not illustrated) such as titanium nitride (TiN), tungsten (W), cobalt (Co), aluminum (Al), or the like is deposited on the high-k dielectric to form the replacement metal gate. The conductive material may be formed using any suitable deposition process such as, but not limited to, atomic layer deposition (ALD) in order to ensure the formation.

In some embodiments, the method 10 is integrated such that there is no vacuum break. In one or more embodiments, formation of the superlattice structures 108, 114 (operation 12), nanosheet patterning (operation 14), dummy gate patterning (operation 16), spacer formation (18), source/drain formation (operation 20), nanosheet release (operation 22), and replacement gate formation (operation 24) can be integrated such that there is no vacuum break between the operations.

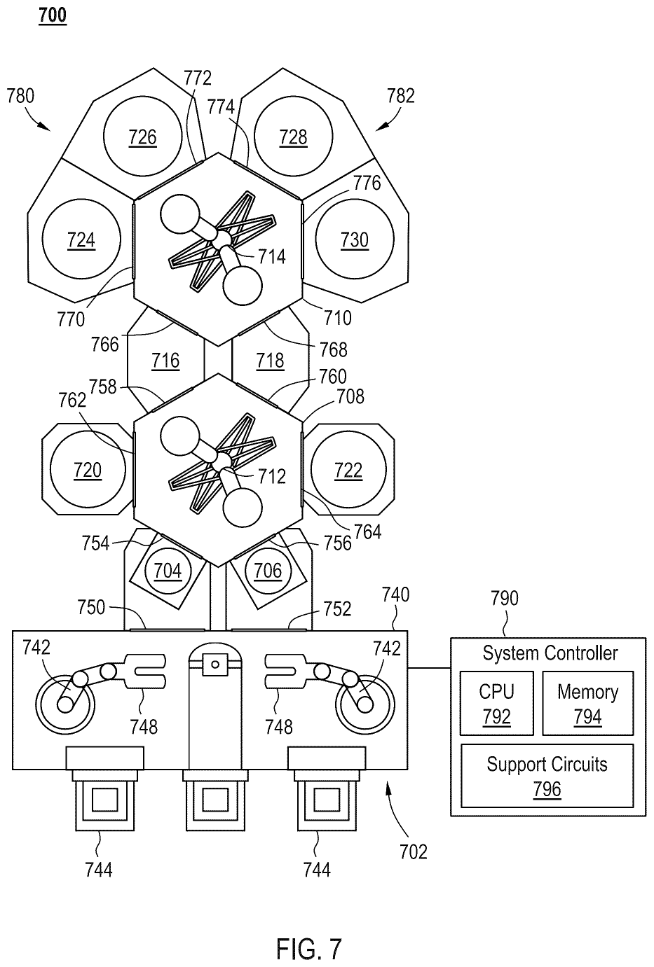

Additional embodiments of the disclosure are directed to processing tools 300 for the formation of the gate-all-around (GAA) devices, FinFETs, and CFETs and methods described, as shown in FIG. 7. FIG. 7 illustrates a schematic top-view diagram of an example of a multi-chamber processing system 700 according to embodiments of the present disclosure. The processing system 700 generally includes a factory interface 702, load lock chambers 704, 706, transfer chambers 708, 710 with respective transfer robots 712, 714, holding chambers 716, 718, and processing chambers 720, 722, 724, 726, 728, 730. As detailed herein, wafers in the processing system 700 can be processed in and transferred between the various chambers without exposing the wafers to an ambient environment exterior to the processing system 700 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 700. Accordingly, the processing system 700 may provide an integrated solution for some processing of wafers.

Examples of a processing system that may be suitably modified in accordance with the teachings provided herein include any integrated processing system or other suitable processing system commercially available.

In the illustrated example of FIG. 7, the factory interface 702 includes a docking station 740 and factory interface robots 742 to facilitate transfer of wafers. The docking station 740 is configured to accept one or more front opening unified pods (FOUPs) 744. In some examples, each factory interface robot 742 generally comprises a blade 748 disposed on one end of the respective factory interface robot 742 configured to transfer the wafers from the factory interface 702 to the load lock chambers 704, 706.

The load lock chambers 704, 706 have respective ports 750, 752 coupled to the factory interface 702 and respective ports 754, 756 coupled to the transfer chamber 708. The transfer chamber 708 further has respective ports 758, 760 coupled to the holding chambers 716, 718 and respective ports 762, 764 coupled to processing chambers 720, 722. Similarly, the transfer chamber 710 has respective ports 766, 768 coupled to the holding chambers 716, 718 and respective ports 770, 772, 774, 776 coupled to processing chambers 724, 726, 728, 730. The ports 754, 756, 758, 760, 762, 764, 766, 768, 770, 772, 774, 776 can be, for example, slit valve openings with slit valves for passing wafers therethrough by the transfer robots 712, 714 and for providing a seal between respective chambers to prevent a gas from passing between the respective chambers. Generally, any port is open for transferring a wafer therethrough. Otherwise, the port is closed.

The load lock chambers 704, 706, transfer chambers 708, 710, holding chambers 716, 718, and processing chambers 720, 722, 724, 726, 728, 730 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 742 transfers a wafer from a FOUP 744 through a port 750 or 752 to a load lock chamber 704 or 706. The gas and pressure control system then pumps down the load lock chamber 704 or 706. The gas and pressure control system further maintains the transfer chambers 708, 710 and holding chambers 716, 718 with an interior low pressure or vacuum environment (which may include an inert gas). Hence, the pumping down of the load lock chamber 704 or 706 facilitates passing the wafer between, for example, the atmospheric environment of the factory interface 702 and the low pressure or vacuum environment of the transfer chamber 708.

With the wafer in the load lock chamber 704 or 706 that has been pumped down, the transfer robot 712 transfers the wafer from the load lock chamber 704 or 706 into the transfer chamber 708 through the port 754 or 756. The transfer robot 712 is then capable of transferring the wafer to and/or between any of the processing chambers 720, 722 through the respective ports 762, 764 for processing and the holding chambers 716, 718 through the respective ports 758, 760 for holding to await further transfer. Similarly, the transfer robot 714 is capable of accessing the wafer in the holding chamber 716 or 718 through the port 766 or 768 and is capable of transferring the wafer to and/or between any of the processing chambers 724, 726, 728, 730 through the respective ports 770, 772, 774, 776 for processing and the holding chambers 716, 718 through the respective ports 766, 768 for holding to await further transfer. The transfer and holding of the wafer within and among the various chambers can be in the low pressure or vacuum environment provided by the gas and pressure control system.

The processing chambers 720, 722, 724, 726, 728, 730 can be any appropriate chamber for processing a wafer. In some embodiments, the processing chamber 720 can be capable of performing an annealing process, the processing chamber 722 can be capable of performing a cleaning process, and the processing chambers 724, 726, 728, 730 can be capable of performing epitaxial growth processes. In some examples, the processing chamber 722 can be capable of performing a cleaning process, the processing chamber 720 can be capable of performing an etch process, and the processing chambers 724, 726, 728, 730 can be capable of performing respective epitaxial growth processes. The processing chamber 722 may be any suitable preclean chamber known to the skilled artisan. The processing chamber 720 may be any suitable etch chamber known to the skilled artisan.

A system controller 790 is coupled to the processing system 400 for controlling the processing system 700 or components thereof. For example, the system controller 790 may control the operation of the processing system 700 using a direct control of the chambers 704, 706, 708, 716, 718, 710, 720, 722, 724, 726, 728, 730 of the processing system 700 or by controlling controllers associated with the chambers 704, 706, 708, 716, 718, 710, 720, 722, 724, 726, 728, 730. In operation, the system controller 790 enables data collection and feedback from the respective chambers to coordinate performance of the processing system 700.

The system controller 790 generally includes a central processing unit (CPU) 792, memory 794, and support circuits 796. The CPU 792 may be one of any form of a general-purpose processor that can be used in an industrial setting. The memory 794, or non-transitory computer-readable medium, is accessible by the CPU 792 and may be one or more of memory such as random-access memory (RAM), read only memory (ROM), floppy disk, hard disk, or any other form of digital storage, local or remote. The support circuits 796 are coupled to the CPU 792 and may comprise cache, clock circuits, input/output subsystems, power supplies, and the like. The various methods disclosed herein may generally be implemented under the control of the CPU 792 by the CPU 792 executing computer instruction code stored in the memory 794 (or in memory of a particular process chamber) as, for example, a software routine. When the computer instruction code is executed by the CPU 792, the CPU 792 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 708, 710 and the holding chambers 716, 718. In other examples, more or fewer transfer chambers (e.g., one transfer chamber) and/or more or fewer holding chambers (e.g., no holding chambers) may be implemented as a transfer apparatus in a processing system.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor logic device, the method comprising:
forming a first superlattice structure on a substrate, the first superlattice structure comprising a plurality of first layers comprising silicon and a corresponding plurality of second layers comprising at least 25% germanium alternatingly arranged in a plurality of stacked pairs extending between a source region and a drain region;
forming a second superlattice structure on the substrate, the second superlattice structure comprising a plurality of third layers comprising in a range of from 5% to 15% germanium and a corresponding plurality of fourth layers comprising at least 25% germanium alternatingly arranged in a plurality of stacked pairs extending between the source region and the drain region; and
selectively etching the plurality of second layers and the plurality of fourth layers simultaneously to form an nMOS transistor and a pMOS transistor.

2. The method of claim 1, wherein each of the plurality of third layers comprise silicon germanium having in a range of from 5% to 10% germanium.

3. The method of claim 1, wherein each of the plurality of second layers comprise silicon germanium having at least 25% germanium.

4. The method of claim 1, wherein each of the plurality of fourth layers comprise silicon germanium having at least 25% germanium.

5. The method of claim 1, wherein forming the second superlattice structure comprises bottom-up growth of the plurality of fourth layers and bottom-up growth of the plurality of third layers.

6. The method of claim 1, wherein forming the second superlattice structure comprises bottom-up grown of the plurality of fourth layers and HCL sidewall etch back to grow the plurality of third layers.

7. The method of claim 1, wherein forming the second superlattice structure comprises bottom-up growth of the plurality of fourth layers and conformal deposition of the plurality of third layers.

8. The method of claim 1, further comprising forming a first gate structure on the first superlattice structure and a second gate structure on the second superlattice structure.

9. The method of claim 1, further comprising forming the source region adjacent a first end of the first superlattice structure and the drain region adjacent a second opposing end of the first superlattice structure.

10. The method of claim 8, further comprising forming sidewall spacers on an outer sidewall of the first gate structure and the second gate structure.

11. The method of claim 10, further comprising depositing an interlayer dielectric (ILD) layer on the semiconductor logic device.

12. The method of claim 8, further comprising recessing the plurality of second layers and recessing the plurality of fourth layers from the second superlattice structure.

13. The method of claim 8, wherein the first gate structure and the second gate structure independently comprise one or more of titanium nitride (TiN), tantalum nitride (TaN), tungsten (W), and titanium aluminum (TiAl).

14. The method of claim 1, wherein the method is performed in a processing chamber without breaking vacuum.

15. The method of claim 1, wherein the semiconductor logic device comprises a gate all around.

16. A semiconductor logic device comprising:
an n-channel gate-all-around (n-GAA) field-effect transistor on a substrate; and
a p-channel gate-all-around (p-GAA) field-effect transistor on the substrate adjacent to the n-channel gate-all-around (n-GAA) field-effect transistor,
wherein the n-channel gate-all-around (n-GAA) field-effect transistor comprises a first superlattice structure including a plurality of first layers comprising silicon and a corresponding plurality of second layers comprising at least 25% germanium alternatingly arranged in a plurality of stacked pairs extending between a source region and a drain region, and wherein the p-channel gate-all-around (p-GAA) field-effect transistor includes a plurality of third layers comprising in a range of from 5% to 15% germanium and a corresponding plurality of fourth layers comprising at least 25% germanium alternatingly arranged in a plurality of stacked pairs extending between the source region and the drain region.

17. The semiconductor logic device of claim 16, wherein each of the plurality of third layers comprise silicon germanium having in a range of from 5% to 10% germanium.

18. The semiconductor logic device of claim 16, wherein each of the plurality of second layers comprise silicon germanium having at least 25% germanium.

19. The semiconductor logic device of claim 16, wherein each of the plurality of fourth layers comprise silicon germanium having at least 25% germanium.

20. A non-transitory computer readable medium including instructions, that, when executed by a controller of a processing chamber, causes the processing chamber to perform the operations of:
form a first superlattice structure on a substrate, the first superlattice structure comprising a plurality of first layers comprising silicon and a corresponding plurality of second layers comprising at least 25% germanium alternatingly arranged in a plurality of stacked pairs extending between a source region and a drain region;
form a second superlattice structure on the substrate, the second superlattice structure comprising a plurality of third layers comprising in a range of from 5% to 15% germanium and a corresponding plurality of fourth layers comprising at least 25% germanium alternatingly arranged in a plurality of stacked pairs extending between the source region and the drain region; and
selectively etch the plurality of second layers and the plurality of fourth layers simultaneously to form an nMOS transistor and a pMOS transistor.
